(19) United States
(12) Patent Application Publication
(10) Pub. No.: US 2009/0142227 A1
(43) Pub. Date: Jun. 4, 2009

(54) Parylene Coating and Method for the Production Thereof

(76) Inventors: Manfred Fuchs, Nurnberg (DE); Karsten Heuser, Erlangen (DE); Ralph Patzold, Roth (DE); Markus Schild, Herzogenaurach (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/994,184

(22) PCT Filed: Jun. 19, 2006
(86) PCT No.: PCT/EP2006/063309

§ 371 Date: Jul. 28, 2008

(30) Foreign Application Priority Data
Jul. 1, 2005 (DE) 10 2005 030 833.3

(51) Int. Cl. B01J 19/00; B05D 7/24; C23C 16/448; C23C 16/46

(52) U.S. Cl. 422/50; 427/226; 427/96.8; 427/74; 427/96.2; 427/585

(57) ABSTRACT

In a method for producing a parylene coating on a substrate containing an integrated electronic component which is e.g. an x-ray detector, the following steps are provided: vaporization of parylene; pyrolyzation of the vaporized parylene; polymerization of the pyrolyzed parylene, the polymerized parylene being deposited on a cooled substrate. The method provides controllable, patterned deposition of parylene on the cooled and/or heated substrate, the advantage being that x-ray converters, for example, can be anticorrosively encapsulated and a penetration depth of the parylene between phosphor needles or storage phosphor needles can be controlled, resulting in an improved resolution and improved modulation transfer function of electronic components.

### CROSS REFERENCE TO RELATED APPLICATION

This application is a U.S. national stage application of International Application No. PCT/EP2006/0063309 filed Jun. 19, 2006, which designates the United States, and claims priority to German application number 10 2005 030 833.3 filed Jul. 1, 2005, the contents of which are hereby incorporated by reference in its entirety.

### TECHNICAL FIELD

The present invention relates to a parylene coating and a method for producing a parylene coating for an x-ray converter. In particular the invention relates to a method for producing a parylene C coating for an x-ray converter, in which method the substrate is cooled.

### BACKGROUND

In order to achieve maximally long-term functionality for electronic, optical or medical components, appropriate protective coatings are required on the systems used.

For this purpose, parylene coatings are used on a large scale these days as so-called anticorrosion coatings.

Parylene and in particular parylene C demonstrably possesses one of the lowest water vapor permeation rates in relation to organic coatings.

Parylene is a generic term for a completely linear, partially crystalline and uncrosslinked polymer group. Since the discovery of a manufacturing process in the mid-20^{th} century, this polymer family has been steadily growing. Although the various groups possess different properties, the four industrially used types of parylene produce a pinhole-free conformal substrate coating.

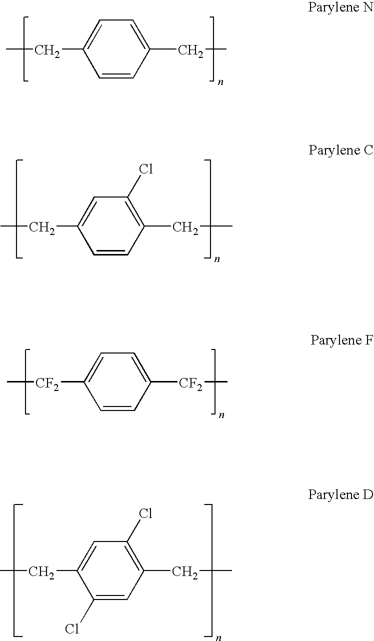

Parylene C (poly-monochloro-para-xylylene) is the variant most used for coatings. As compared to parylene N, it possesses a chlorine atom on the benzene ring.

This results in a good combination of mechanical and electrical properties, as well as very low permeability to moisture and corrosive gases.

Although parylene C deposits much quicker than parylene N, the trench coating is not as good. At 290° C., the melting point of parylene C is the lowest of the abovementioned types of parylene.

In the prior art, parylene coatings are applied by chemical vapor deposition (CVD) in a vacuum coating system (see FIG. 1), the equipment basically consisting of three different temperature and pressure areas which are interconnected. After the third section, a cold trap is installed containing the substrate mounted on a substrate holder, followed by a vacuum pump.

By means of the CVD process, parylene C is evenly and conformally applied and is therefore also suitable for 3D structures.

While this completely three-dimensional growth is greatly advantageous for many applications, there exist applications where patterned deposition is desirable.

For example, the contact-making elements of a circuit board have to be kept coating-free to allow the electrical leads to be attached.

Hitherto no technically relevant method has been available for direct patterning of parylene. In the prior art the substrate is therefore first completely coated and the coating is then ablated at defined locations.

This ablation can be performed using various methods, e.g. etching away by a plasma system or parylene removal by laser ablation.

The most commonly used method involves patterning by means of shadow masks, the disadvantage of this being that during parylene coating a film is produced which covers and therefore also bonds mask and substrate.

To separate mask and substrate, another processing step must be performed in order to cut through the film, thereby making the method cost-intensive.

In addition, control over the geometry of the open area is difficult to achieve.

Thus it is desirable, for example, to obtain a gradual reduction in film thickness toward the open area in order to avoid separation edges for subsequent coatings.

In addition, when coating a phosphor layer or storage phosphor layer for x-ray converters with a parylene encapsulating film in order to minimize the effect of ambient humidity, because of the high crevice penetration of the parylene film in the case of CVD coating, there occurs a “sealing” of the crevices and cracks produced in the phosphor layer during coating.

As the parylene film has a similar refractive index to the phosphor layer or storage phosphor layer which consist of CsI:Na, CsI:Tl or CsBr:Eu, the light guiding effect of the phosphor needles in the converter is nullified.

This results in increased crosstalk or rather increased transfer of light between the individual phosphor needles.

As a consequence, the modulation transfer function (MTF) of the phosphor layers is markedly reduced.

Until now parylene C has been used to encapsulate such optically active needle structures, the associated penalties in respect of the optical resolution of the resulting image being accepted.

WO 99/66346, for example, discloses a sensor in which sealing of the parylene film occurs between the phosphor needles over the photodetectors, resulting in the to date accepted deteriorations in image quality (resolution, light guiding, modulation transfer function).

This can realized only with difficulty using the specified methods.

### SUMMARY

Therer exists a need for a method and an apparatus which will permit parylene to be applied between the phosphor layers or storage phosphor layers of the phosphor needles of an x-ray converter.

According to an embodiment, a method for producing a parylene coating on a substrate, may comprise the following steps: vaporizing parylene; pyrolyzing the deposited parylene, polymerizing the pyrolyzed parylene, and depositing the polymerized parylene on a cooled substrate.

According to a further embodiment, in pre-defined areas, the substrate temperature of the substrate holder can be reduced by at least one cooling device and/or increased by at least one heating device. According to a further embodiment, the temperature of the substrate holder may be in a pre-defined range between −100° C. and +20° C. According to a further embodiment, the temperature of the substrate holder may be preferably in a range between −20° C. and +20° C. According to a further embodiment, the parylene coating may correspond to an encapsulation. According to a further embodiment, the method can be used for encapsulating at least one x-ray converter. According to a further embodiment, at least one photodetector may be embedded in the substrate. According to a further embodiment, the substrate may comprise at least one circuit board. According to a further embodiment, the at least one photodetector embedded in the substrate may be be electrically contacted after encapsulation. According to a further embodiment, the heating wire may be contacted on the substrate by means of an adhesive foil. According to a further embodiment, after deposition of the parylene coating at least one metal line may be applied to the substrate by means of a shadow mask. According to a further embodiment, edge areas between a parylene coating and an uncoated area may be covered by means of a metal line. According to a further embodiment, the coating material may comprise parylene, preferably parylene C. According to a further embodiment, the parylene coating can be applied by means of a chemical vapor deposition process. According to a further embodiment, the parylene coating can be applied by means of vapor deposition polymerization. According to a further embodiment, the parylene coating can be applied by means of a physical vapor deposition process. According to a further embodiment, the parylene coating can be applied to encapsulate at least one x-ray converter by means of a multilayer system of reflecting metal and parylene C. According to a further embodiment, the parylene coating can be used to encapsulate at least one circuit board and/or electronic component.

According to another embodiment, an electronic component may comprise a parylene coating being applied to the electronic component, a substrate on which a detector is disposed, at least two phosphor needles spaced apart from one another being applied to the detector, wherein between the at least two phosphor needles, the parylene coating has a defined film thickness which does not completely fill up the space between the phosphor needles.

According to a further embodiment, the parylene coating can be applied homogeneously between the at least two phosphor needles. According to a further embodiment, the electronic component may comprise an x-ray converter. According to a further embodiment, the detector may comprise a photodetector. According to a further embodiment, the electronic component may comprise a circuit board. According to a further embodiment, the electronic component may comprise an x-ray converter. According to a further embodiment, the electronic component may comprise a photodetector. According to a further embodiment, the patterned parylene coating may comprise parylene C. According to a further embodiment, the parylene coating can be used to encapsulate at least one electronic component. According to a further embodiment, the phosphor needles may comprise CsI and/or CsI:Na and/or CsI:Tl and/or CsBr:Eu.

### BRIEF DESCRIPTION OF THE DRAWINGS

Further advantages, features and possible applications of the present invention will emerge from the following description of preferred embodiments in conjunction with the accompanying drawings, in which:

FIG. 1 schematically illustrates a conventional vacuum coating system for parylene coating.

FIG. 1a schematically illustrates a preferred embodiment of a vacuum coating system for coating with parylene, a cooling device being attached to the substrate.

FIG. 2 shows a schematic plan view of an electronic component which is mounted on or embedded in a substrate and is provided with a cooling device.

FIG. 3 shows a schematic plan view of an electronic component which is mounted on or embedded in a substrate and is provided with a cooling device after it has been coated with parylene.

FIG. 4 shows a schematic plan view of an electronic component which is mounted on or embedded in a substrate and is provided with a cooling device after electrical contact has been established by means of a metal contact.

FIG. 5 shows a schematic cross-sectional view of an x-ray converter which has been coated by means of a conventional parylene coating method.

FIG. 6 shows a schematic cross-sectional view of an x-ray converter which has been coated by means of a parylene coating method according to an embodiment, the substrate having been cooled.

### DETAILED DESCRIPTION

As stated above according to an embodiment, a method for producing a parylene coating on a substrate, may comprise the following steps: Vaporizing parylene; Pyrolyzing the vaporized parylene; Polymerizing the pyrolyzed parylene, the polymerized parylene being deposited on a cooled substrate.

In the method according to an embodiment, a cooled substrate has the advantage of providing a patterned coating, as the parylene coating on a substrate is dependent to a large extent on the temperature of the substrate.

Thus, it is found that when the substrate temperature is reduced from ambient temperature, the adsorption coefficient and therefore the growth rate of the parylene film can be increased many times over.

For example, by changing the substrate temperature from +20° C. to −20° C., the growth rate of a parylene film can be increased by more than one order of magnitude.

If, for example, the substrate is cooled via the substrate holder, but defined sub-areas of the substrate are heated e.g. by means of a heating wire, it can be achieved that only the defined cooler areas of the substrate are coated with parylene.

By cooling the substrate it can likewise be controlled that the parylene film only assumes a certain thickness between the phosphor or storage phosphor needles of an electronic component such as an x-ray converter.

In addition, it may be advantageous that, because of the temperature gradient created during coating, a continuously increasing or decreasing film thickness is produced between coated and uncoated area and the formation of a separation edge can be avoided.

Moreover, the penetration depth of the parylene into crevices and intervening spaces can be controlled by varying the substrate temperature.

Controlling the substrate temperature makes a parylene process possible in which the optical crosstalk between the individual optical centers can be minimized.

This means that parylene can be prevented from penetrating the spaces between the individual CsI structures, such as phosphor needles or storage phosphor needles, of the elements, which are not optically linked by the parylene.

Linking of the elements in particular causes light guiding between the individual phosphor needles and storage phosphor needles which reduces the resolution of the optical component and its modulation transfer function (MTF).

Therefore, by suitably selecting the substrate temperature, the geometry of an open area and the penetration depth for a component to be coated can be optimally controlled.

According to another embodiment, with the method for producing a parylene coating on a substrate, the substrate holder is cooled in pre-defined areas. The advantage of this is that parylene coating takes place in pre-defined areas and no separation edge is formed between the coated and the uncoated area.

According to various embodiments, it may be additionally preferred that, for the method for producing a parylene coating on a substrate, the substrate temperature of the substrate holder is in a pre-defined range between −100° C. and +30° C. The advantage of this is that parylene coating according to various embodiments takes place in pre-defined areas and no separation edge is formed between the coated and the uncoated area.

According to another embodiment, with the method for producing a parylene coating on a substrate it is preferred that the substrate temperature of the substrate holder is preferably in a range between −20° C. and +30° C. The advantage of this is that the growth rate of the coating thickness can be increased by more than one order of magnitude.

According to another embodiment of a method for producing a parylene coating on a substrate, the patterned parylene coating corresponds to an encapsulation. The advantage of this is that the method can be used for coating sensitive electronic and optical components.

According to another embodiment, in the case of a method for producing a parylene coating on a substrate, the method is used for encapsulating at least one x-ray detector. The advantage of this is that sensitive electronic and optical components can be coated in an inexpensive and simple manner.

According to another embodiment, in the case of a method for producing a parylene coating on a substrate, at least one photodetector is embedded in the substrate. The advantage of this is that sensitive electronic and optical components can be coated in an inexpensive and simple manner.

According to another embodiment, in the case of a method for producing a parylene coating on a substrate, the substrate comprises at least one circuit board containing electronic components. The advantage of this is that sensitive electronic and optical components can be coated in an inexpensive and simple manner.

According to another embodiment, in the case of a method for producing a parylene coating on a substrate, the photodetectors embedded in the substrate are electrically contacted after encapsulation. The advantage of this is that sensitive electronic and optical components can be coated in an inexpensive and simple manner and provided with metal lines.

According to another embodiment, in the case of a method for producing a parylene coating on a substrate and/or substrate holder, the cooling device is contacted on the substrate and/or substrate holder by means of an adhesive foil. The advantage of this is that with the method the cooling device can be easily attached to and removed again from the substrate and/or substrate holder.

According to another embodiment, in the case of a method for producing a parylene coating on a substrate, after application of the parylene coating, at least one metal line is applied to the substrate by means of a shadow mask. The advantage of this is that the metal line can be applied in a simple, inexpensive and patterned manner.

According to another embodiment, in the case of a method for producing a parylene coating on a substrate, edge areas between a parylene coating and an uncoated area are covered by means of a metal line. The advantage of this is that the metal line covers homogeneously between the edge areas of a parylene coating and an uncoated area and no sections of the uncoated area are exposed.

According to another embodiment, in the case of a method for producing a parylene coating on a substrate, the coating material comprises parylene, preferably parylene C. The advantage of this is that parylene C produces better film properties (growth rate, permeability, etc.).

According to another embodiment, in the case of a method for producing a parylene coating on a substrate, the parylene coating is applied by means of a chemical vapor deposition (CVD) process. The advantage of this is that the method can be used in a simple and inexpensive manner.

According to another embodiment, in the case of a method for producing a parylene coating on a substrate, the parylene coating is applied by means of vapor deposition polymerization (VDP). The advantage of this is that the method can be used in a simple and inexpensive manner.

According to another embodiment, in the case of a method for producing a parylene coating on a substrate, the parylene coating is applied by means of a physical vapor deposition (PVD) process. The advantage of this is that the method can be used in a simple and inexpensive manner.

According to another embodiment, in the case of a method for producing a parylene coating on a substrate, parylene coating is performed for encapsulating at least one x-ray converter by means of a multilayer system of reflecting metal and parylene C. The advantage of this is that the coating can be applied to the substrate in a simple and inexpensive manner by means of such a method.

According to another embodiment, with a method for producing a parylene coating on a substrate, the parylene coating is used for encapsulating at least one circuit board and/or one electronic component. The advantage of this is that circuit boards and/or electronic components can be encapsulated in a simple and inexpensive manner.

According to another embodiment, said parylene coating is applied to an electronic component, and the electronic component comprising:

a substrate on which a detector is disposed, there being applied to the detector at least two phosphor needles which are spaced apart from one another, the parylene coating between the at least two phosphor needles having a defined film thickness which does not completely fill the space between the phosphor needles.

The advantage of this is that the space between the phosphor needles is not filled up, which means that the electronic component has a higher performance, a higher resolving capability and an improved modulation transfer function (MTF).

According to another embodiment, the parylene coating is applied in a homogeneous manner between the at least two phosphor needles. The advantage of this is that the electronic component has a higher performance, a higher resolving capability and an improved modulation transfer function (MTF).

According to another embodiment, the electronic component may comprise an x-ray converter. The advantage of this is that the embodiments can be used for encapsulating x-ray converters.

According to another embodiment, the detector may comprise a photodetector. The advantage of this is that the present embodiments can be used in an application-specific manner.

According to another embodiment, the electronic component has a circuit board. The advantage of this is that coating can be carried out in a simple and inexpensive manner.

According to another embodiment, the electronic component has an x-ray converter. The advantage of this is that coating can be carried out in a simple and inexpensive manner.

According to another embodiment, the electronic component has a photodetector. The advantage of this is that coating can be carried out in a simple and inexpensive manner.

According to another embodiment, the patterned parylene coating consists of parylene C. The advantage of this is that coating can be carried out in a simple and inexpensive manner.

According to another embodiment, the parylene coating is used for encapsulating at least one electronic component. The advantage of this is that the embodiments can be used in an application-specific manner.

According to another embodiment, the phosphor needles comprise CsI and/or CsI:Na and/or CsI:Tl and/or CsBr:Eu. The advantage of this is that coating can be carried out in a simple and inexpensive manner.

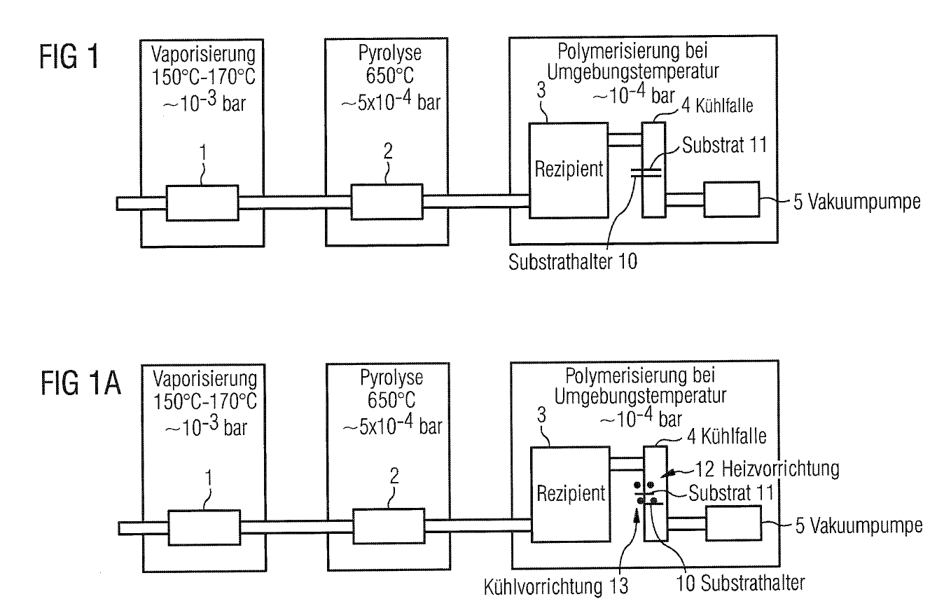

FIG. 1 schematically illustrates a vacuum coating system for parylene coating according to the prior art.

A coating system is shown which has, in its first area, a vaporization section 1, a second area 2 which is used to pyrolize the parylene, and a third area 3 which is used to polymerize the parylene.

The polymerization section 3 is followed by cold trap 4 which has a substrate holder 10 with a substrate 11 inserted, as well as a vacuum pump 5 which provides an appropriate vacuum.

The first section i.e. the vaporization section 1 contains the unsublimated powdery parent substance of the parylene. At temperatures around 160° C. and a pressure of 10⁻³ bar the powder vaporizes and is fed to the second section, the pyrolysis furnace.

During pyrolysis 2, at a temperature of 650° C. and a pressure of approximately 5×10⁻⁴ bar, the sublimate is cleaved into two reactive monomers.

The deposition of the parylene on the substrate surfaces 11 by polymerization of the monomers takes place at ambient temperature in the third section 3 (vacuum chamber).

Because of the adsorption and desorption processes of the monomers during deposition, reactions take place not only on the surface of the parylene film, but in particular by diffusion of the monomers in the polymer layer.

In the cold trap 4 following the vacuum chamber 3 is a substrate holder 10 containing the substrate 11 to be coated with parylene.

FIG. 1a shows a schematic of a preferred embodiment of a vacuum coating system for coating with parylene, a cooling device 13 and/or a heating device 12 being mounted on the substrate 11 or under the substrate 11.

This illustrates a coating system which has, in its first area, a vaporization section 1, a second area 2 which is used to pyrolize the parylene and a third area 3 which is used to polymerize the parylene.

The polymerization section 3 is followed by cold trap 4 which has a substrate holder 10 with a substrate 11 inserted, as well as a vacuum pump 5 which provides an appropriate vacuum.

The first section i.e. the vaporization section 1 contains the unsublimated powdery parent substance of the parylene. At temperatures around 160° C. and a pressure of 10⁻³ bar the powder vaporizes and is fed to the second section 2, the pyrolysis furnace.

During pyrolysis 2 at a temperature of 650° C. and a pressure of approximately 5×10⁻⁴ bar, the sublimate is cleaved into two reactive monomers.

The deposition of the parylene on the substrate surfaces 11 by polymerization of the monomers takes place at ambient temperature in the third section (vacuum chamber 3).

Because of the adsorption and desorption processes of the monomers during deposition, reactions take place not only on the surface of the parylene film, but in particular by diffusion of the monomers in the polymer layer.

In the cold trap 4 following the vacuum chamber is a substrate holder 10 containing the substrate 11 to be coated with parylene.

In one embodiment, the substrate holder 10 is provided on its upper side or underside with a cooling device 13 and/or a heating device 12 which is in thermal contact with the substrate holder.

It is likewise possible, in another embodiment, for the cooling device 13 and the heating device 12 to be mounted directly on the upper side and/or underside of the substrate 11 by means of an adhesive foil or other adhesive material.

The geometry of the heating or cooling device 12, 13 can take any form and be designed to suit the particular application.

The cooling device 12 preferably extends under the substrate 11 in an area underlying the electronic component 22, 32, 42 to be coated, such as an x-ray converter, for example.

The heating device 12, on the other hand, is in an area 23, 33, 43 which is to be kept free of parylene and which is subsequently used for establishing electrical contact with an electronic component 22, 32, 42.

The substrate temperature of the substrate 11 to be cooled can range between −100° C. and +30° C., preferably between −20° C. and +30° C.

The substrate temperature of the substrate 11 to be heated can range between +20° C. and +100° C., preferably between +20° C. and +50° C.

Any basic electronic component structure such as a circuit board can be used as a substrate 11, an electronic component such as a photodetector or an x-ray converter being embeddable in said substrate.

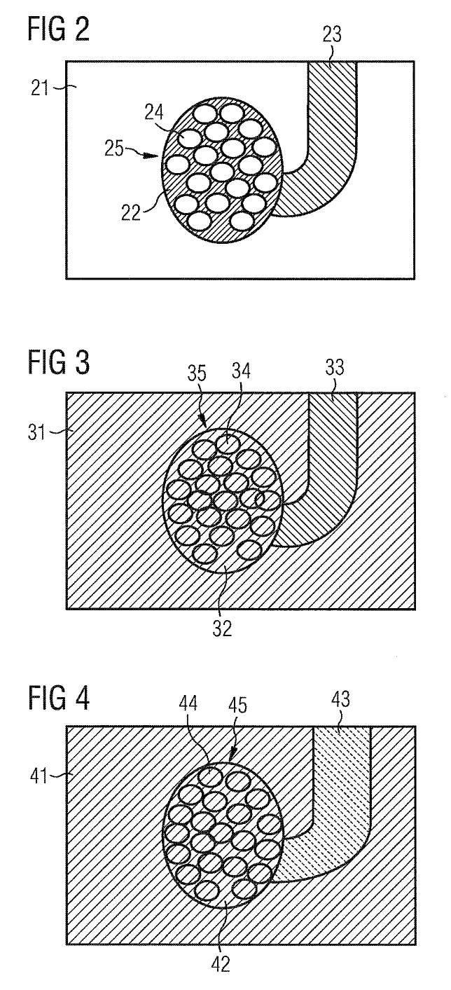

FIG. 2 shows a schematic plan view of an electronic component 22, such as a photodetector or an x-ray converter, which is mounted on or embedded in a substrate 21. A cooling device 25 and a heating device 23 are mounted on the surface of the substrate 21 facing away from the substrate holder 10 or on the surface of the substrate 21 facing the substrate holder 10, said devices being in thermal contact with the substrate 21 and cooling and heating same in a defined area. In addition, phosphor needles 24 or storage phosphor needles 24 are disposed in the electronic component 22.

Preferably an area of the substrate 21 is heated which is intended for subsequently establishing contact to an electronic component 22 and, in addition, an area of the substrate 21 is cooled which lies directly below the electronic component 22 so that the latter can be appropriately cooled.

The cooling device 23 is used to achieve an appropriate parylene growth rate on pre-defined areas of the substrate, a higher growth rate and better adhesion of parylene being produced on a cooled substrate area 25.

By cooling the electronic component 22 and associated phosphor needles or storage phosphor needles 24, the penetration depth of parylene in the space between the phosphor needles or storage phosphor needles 24 can be controlled.

This makes possible a parylene process in which optical crosstalk between the individual optical centers can be minimized, because penetration of parylene into the spaces between the individual CsI structures causes the elements of the phosphor needles 24 and storage phosphor needles 24 to be linked together, resulting in light guidance between the individual phosphor needles 24 or storage phosphor needles 24 and thereby reducing the resolution or modulation transfer function of the optical component 22.

Therefore with a parylene coating according to an embodiment, a cooled substrate 21 enables the penetration depth into the spaces between the phosphor needles 24 or storage phosphor needles 24 to be reduced to a minimum.

On the other hand, in the area of the heating device 23, because of the increased substrate temperature, no adequate adhesion is produced during subsequent coating with parylene, which means that no coating with parylene occurs in this area.

The advantage of this area is that the electronic component 22 can subsequently be easily electrically contacted via the area which is not coated with parylene.

FIG. 3 shows a schematic plan view of an electronic component 32, such as a photodetector or an x-ray converter, which is mounted on or embedded in a substrate 31 and is provided with a heating device 33 and a cooling device 35, after it has been coated with parylene.

In this case the cooled area below the electronic component 32 has been coated with parylene. An area on the substrate was heated by means of the heating device 33 and therefore not coated with parylene, as this area is subsequently used for establishing electrical contact with the component 32.

It can be seen that the electronic component 32 and the substrate 31 have been coated with parylene. On the other hand, the substrate area heated by the heating device 33 has not been coated with parylene.

Because of the temperature gradient between the heating device 33 and the unheated substrate 31, a uniformly increasing parylene coating is formed from the uncoated substrate area to the coated substrate area.

The uniform increase in the coating means that no separation edges are formed, resulting in a thicker coating and encapsulation of the electronic components.

FIG. 4 shows a schematic plan view of an electronic component 42, such as a photodetector or an x-ray converter, which is mounted on or embedded in a substrate 41 and is provided with a cooling or heating device 33, 35, after electrical contact has been established by means of a metal contact 43.

Also illustrated are the phosphor needles or storage phosphor needles 44 between which, because of the cooled area 45, the parylene has a certain penetration depth which optimizes the optical quality of the electronic component 42.

Because of the cooling or heating device 33, the absorption coefficient of parylene and therefore its growth rate on the substrate 41 can be controlled. The advantage of this is that, because of the temperature gradient between the heated and unheated area on the substrate, the parylene film deposited on the substrate 41 assumes a uniformly increasing form which creates no separation edges.

As no parylene coating is applied to the substrate in the heating area of the heating wire, a metal line is applied to the uncoated area by means of a shadow mask, the areas where the parylene film has been thinned out being covered at the same time.

This results in increased encapsulation density and produces corresponding anticorrosive protection for the electronic component 42.

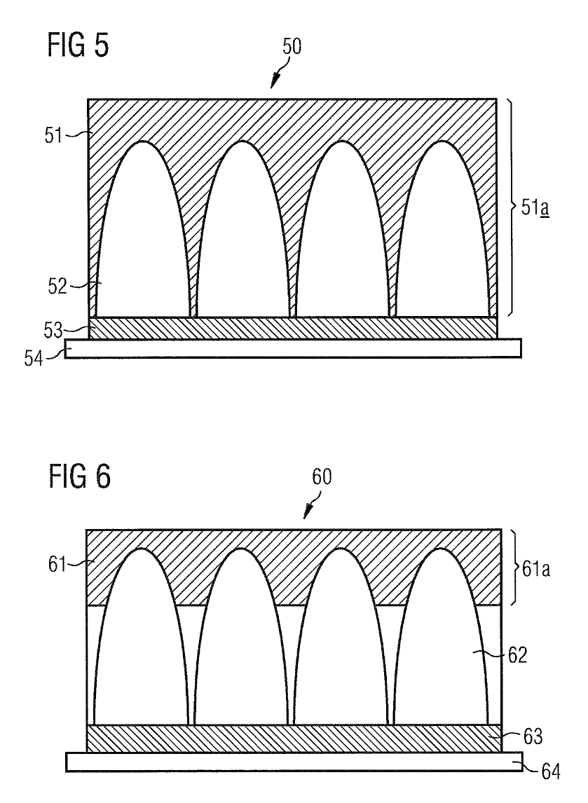

FIG. 5 shows a schematic cross-sectional view of an electronic component, such as an x-ray converter, which has been coated by means of a conventional parylene coating method.

It can be seen here that the parylene film 51 extends into the lower area between the phosphor needles or storage phosphor needles 52 and has a film thickness 51a, the phosphor needles or storage phosphor needles 52 being disposed above a photodetector 53 located on the substrate 54.

Altogether, the components 51, 52 and 53 constitute an electronic component 50 of an x-ray converter.

Because of the geometry of the phosphor needles or storage phosphor needles 52 and the deposition parameters (pressure, substrate temperature, etc), when coating a phosphor layer or storage phosphor layer for x-ray converters with a parylene encapsulating film, due to the high crevice penetration of the parylene film during CVD coating, “sealing” of the gaps and cracks created in the phosphor layer during coating occurs.

As the parylene film 51 has a similar refractive index to the phosphor layer or storage phosphor layer consisting of CsI:Na, CsI:Tl or CsBr:Eu, the light guiding effect of the phosphor needles in the converter is nullified.

This results in increased crosstalk or rather increased transfer of light between the individual phosphor needles 52.

As a consequence, the modulation transfer function (MTF) of the phosphor layers is significantly reduced.

In the prior art, parylene C has been used to encapsulate such optically active needle structures, the associated penalties in respect of the optical resolution of the resulting image being accepted.

Finally, FIG. 6 shows a schematic cross-sectional view of an electronic component 22, 32, 42, e.g. an x-ray converter, which has been coated by means of a parylene coating method according to an embodiment, the substrate 64 having been cooled.

On the substrate 64 are mounted the photodetector 63 of the electronic component 60, e.g. an x-ray converter.

It can be seen here that, because of the cooling of the substrate 64 as has been described above for the method according to an embodiment, the parylene film 61 only penetrates the spaces between the phosphor needles or storage phosphor needles 62 to a certain penetration depth 61a, the space between the phosphor needles 62 not being completely filled up.

In addition, the parylene film 61 can be homogeneously applied between the phosphor needles 62.

This avoids the abovementioned disadvantages arising from the penetration of parylene into the gaps and intervening spaces in the area of the phosphor needles.

Because of the minimized penetration depth 61a, there is reduced or no light guidance between the individual phosphor needles 62, thereby significantly improving the resolution and modulation transfer function of the x-ray converter or electronic component 60.

1. A method for producing a parylene coating on a substrate, comprising the following steps:
vaporizing parylene;
pyrolyzing the deposited parylene,
polymerizing the pyrolyzed parylene, and
depositing the polymerized parylene on a cooled substrate.

2. The method for producing a parylene coating on a substrate according to claim 1, wherein in pre-defined areas, the substrate temperature of the substrate holder can be reduced by at least one cooling device and/or increased by at least one heating device.

3. The method for producing a parylene coating on a substrate according to claim 1, wherein the temperature of the substrate holder is in a pre-defined range between −100° C. and +20° C.

4. The method for producing a parylene coating on a substrate according to claim 1, wherein the temperature of the substrate holder is preferably in a range between −20° C. and +20° C.

5. The method for producing a parylene coating on a substrate according to claim 1, wherein the parylene coating corresponds to an encapsulation.

6. The method for producing a parylene coating on a substrate according to claim 1, wherein the method can be used for encapsulating at least one x-ray converter.

7. The method for producing a parylene coating on a substrate according to claim 1, wherein at least one photodetector is embedded in the substrate.

8. The method for producing a parylene coating on a substrate according to claim 1, the substrate comprises at least one circuit board.

9. The method for producing a parylene coating on a substrate according to claim 7, wherein the at least one photodetector embedded in the substrate can be electrically contacted after encapsulation.

10. The method for producing a parylene coating on a substrate according to claim 1, wherein the heating wire is contacted on the substrate by means of an adhesive foil.

11. The method for producing a parylene coating on a substrate according to claim 1, wherein after deposition of the parylene coating at least one metal line is applied to the substrate by means of a shadow mask.

12. The method for producing a parylene coating on a substrate according to claim 1, wherein edge areas between a parylene coating and an uncoated area are covered by means of a metal line.

13. The method for producing a parylene coating on a substrate according to claim 1, wherein the coating material comprises parylene, preferably parylene C.

14. The method for producing a parylene coating on a substrate according to claim 1, wherein the parylene coating is applied by means of a chemical vapor deposition process.

15. The method for producing a parylene coating on a substrate according to claim 1, wherein the parylene coating is applied by means of vapor deposition polymerization.

16. The method for producing a parylene coating on a substrate according to claim 1, wherein the parylene coating is applied by means of a physical vapor deposition process.

17. The method for producing a parylene coating on a substrate according to claim 1, wherein the parylene coating is applied to encapsulate at least one x-ray converter by means of a multilayer system of reflecting metal and parylene C.

18. The method for producing a parylene coating on a substrate according to claim 1, wherein the parylene coating can be used to encapsulate at least one circuit board and/or electronic component.

19. An electronic component comprising:
a parylene coating being applied to electronic component and said electronic component comprising:
a substrate on which a detector is disposed,
at least two phosphor needles spaced apart from one another being applied to the detector,
wherein between the at least two phosphor needles, the parylene coating has a defined film thickness which does not completely fill up the space between the phosphor needles.

20. The electronic component according to claim 19, wherein the parylene coating is applied homogeneously between the at least two phosphor needles.

21. The electronic component according to claim 19, wherein the electronic component comprises an x-ray converter.

22. The electronic component according to claim 19, wherein the detector comprises a photodetector.

23. The electronic component according to claim 19, wherein the electronic component comprises a circuit board.

24. The electronic component according to claim 19, wherein the electronic component comprises an x-ray converter.

25. The electronic component according to claim 19, wherein the electronic component comprises a photodetector.

26. The electronic component according to claim 19, wherein the patterned parylene coating comprises parylene C.

27. The electronic component according to claim 19, wherein the parylene coating is used to encapsulate at least one electronic component.

28. The electronic component according to claim 19, wherein the phosphor needles comprise CsI and/or CsI:Na and/or CsI:Tl and/or CsBr:Eu.
